(19) United States
(12) Patent Application Publication
(10) Pub. No.: US 2010/0032654 A1
(43) Pub. Date: Feb. 11, 2010

(54) Semiconductor Device Having Silane Treated Interface

(75) Inventors: Jie Zhang, Buffalo Grove, IL (US); Daniel R. Gamota, Palatine, IL (US); Lin Jiang, Chicago, IL (US)

Correspondence Address: MOTOROLA, INC., 1303 EAST ALGONQUIN ROAD, IL01/3RD, SCHAUMBURG, IL, 60196, US

(73) Assignee: MOTOROLA, INC., Schaumburg, IL (US)

(21) Appl. No.: 12/189,373

(22) Filed: Aug. 11, 2008

(51) Int. Cl. H01L 51/10

(52) U.S. Cl. 257/40; 257/E51.006

(57) ABSTRACT

A semiconductor device made on a polymer substrate using graphic arts printing technology uses a printable organic semiconductor. An electrode is situated on the substrate, and a dielectric layer is situated over the electrode. Another electrode(s) is situated on the dielectric layer. The exposed surfaces of the dielectric and the top electrode are treated with a reactive silane to alter the surface of the electrode and the dielectric sufficiently to allow an overlying organic semiconductor layer to have good adhesion to both the electrode and the dielectric. In various embodiments, the electrodes may be printed, and the dielectric layer may also be printed.

### FIELD OF THE INVENTION

The present invention relates generally to semiconductor devices, and more particularly, to printed organic semiconductor devices having a silane treated interface.

### BACKGROUND

There is a continuing desire in the microelectronics industry to miniaturize device components, increase the circuit density in integrated devices, and lower the cost of making the devices to increase their availability to consumers (e.g. large emissive displays, electronic paper, smart cards, and so forth). One field of research has explored the configuration and materials used in traditional, inorganic semiconductors. As the cell size has shrunk, designers have resorted to extremely thin or non-planar films of SiOₓ, but these films have been problematic as they exhibit a decreased reliability due to finite breakdown fields or have other attendant problems such as step coverage and conformality. Thus, new materials have been developed for use in making active dielectric layers, i.e., high-dielectric strength materials to be used in place of thin films of SiOₓ. Besides developing new materials for inorganic semiconductors, the drive toward hybridization and low-cost electronics has precipitated another area of research relating to the development of organic field-effect transistors (FET). Organic materials are attractive for use in electronic devices as they are compatible with plastics and can be easily fabricated to provide low-cost, lightweight, and flexible devices with plastic substrates. At the same time, printing (gravure, flexo, litho) has evolved as an advantageous patterning method for producing feature sizes less than 20 micrometer. However, organic devices provide their own materials constraints, e.g., concerns in developing active materials include their compatibility with and adhesiveness to plastic substrates and stability during processing steps. In addition, the very nature of an organic transistor requires a variety of chemically diverse materials, leaving a chemically heterogeneous surface upon which to adhere the various layers.

As may be appreciated, those in the field of semiconducting devices continue to search for new materials and components to reduce the size, increase the efficiency, simplify the process, and reduce the cost of fabricating the devices. In particular, it would be advantageous in realizing high-performance field-effect transistors to provide solution processable materials compatible with organic semiconductors and printing technologies and processes.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance thereof

FIG. 1 is a cross sectional view of an electrode on a substrate, in accordance with various embodiments.

FIG. 2 is a cross sectional view of a dielectric layer and additional electrodes on the substrate of FIG. 1, in accordance with various embodiments.

FIG. 3 is a cross sectional view of an adhesion and orientation promoting interface layer on the substrate of FIG. 2, in accordance with various embodiments.

FIG. 4 is a cross sectional view of a printed organic semiconductor device, in accordance with various embodiments.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present the various embodiments.

### DETAILED DESCRIPTION

Before describing in detail embodiments that are in accordance with the present various embodiments, it should be observed that the embodiments reside primarily in combinations of method and apparatus components related to organic semiconductor devices. Accordingly, the apparatus components and methods have been represented where appropriate by conventional symbols in the drawings, showing only those specific details that are pertinent to understanding the embodiments so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element. It will be appreciated that embodiments described herein may be comprised of one or more processes and materials that are combined in a novel way to form a new and useful apparatus. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such a semiconductor device with minimal experimentation.

A semiconductor device made on a polymer substrate using graphic arts printing technology uses a printable organic semiconductor. An electrode is situated on the substrate, and a dielectric layer is situated over the electrode. Another electrode(s) is situated on the dielectric layer. The exposed surfaces of the dielectric and the top electrode are treated with a reactive silane to alter the surface of the electrode and the dielectric sufficiently to allow an overlying organic semiconductor layer to have good adhesion to both the electrode and the dielectric. In various embodiments, the electrodes may be printed, and the dielectric layer may also be printed.

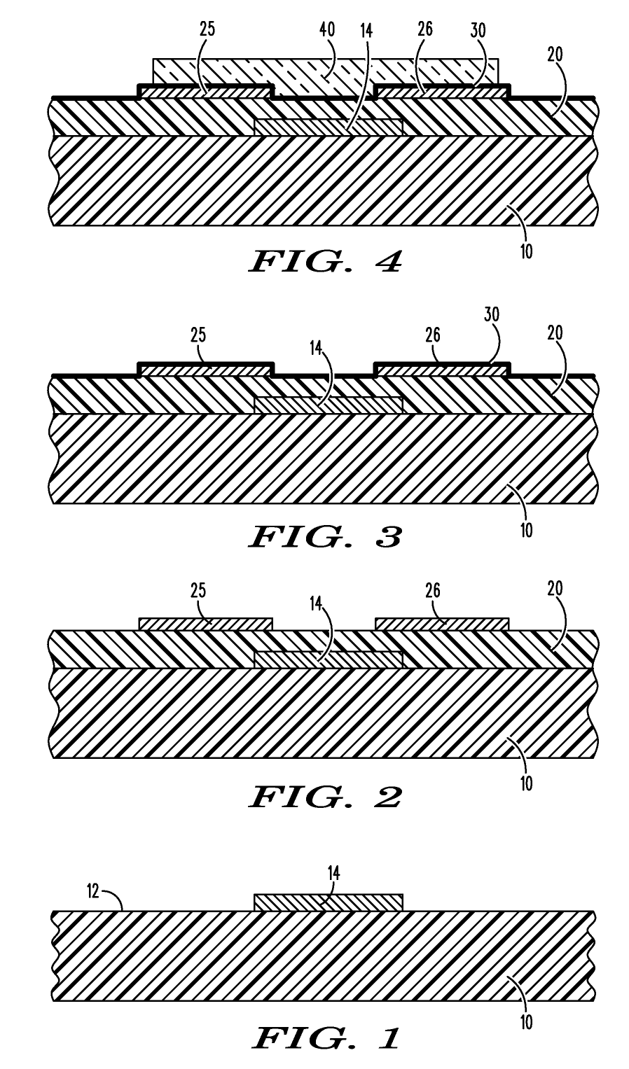

Referring now to FIG. 1, a printed semiconductor device is formed upon a substrate 10. The substrate is typically a polymeric material or a polymeric coated material, rigid or flexible, selected from any of the commonly used polymer substrates in the electronics industry. The polymer substrate is at least 12 microns thick. We find that materials such as polyesters, polyimides, polyamides, polyamide-imides, polyetherimides, polyacrylates, polyethylene, polypropylene, epoxies, polyvinylidene chloride, polysiloxanes, polycarbonates, fabrics, and paper are amenable to use as substrates. An electrode 14 is situated on an upper surface 12 of the substrate. In one embodiment of a semiconductive device, a field effect transistor (FET), the electrode 14 comprises a gate electrode, but other embodiments may include additional electrodes situated in proximity to each other. The electrode 14 is electrically conductive, and in the case of so-called ‘metal’ electrodes, can be aluminum, chromium, copper, gold, iron, nickel, palladium, platinum, silver, titanium, tin, tungsten, zinc or mixtures, layers, or alloys of these materials. Other types of electrically conductive electrodes can also be utilized, such as metal and carbon filled polymers that are printed on the substrate 10. In addition, blends of metals and carbon may also be used. The profile and roughness of the gate electrode is generally less than one-fifth of the thickness of the gate dielectric.

Referring now to FIG. 2, an electrically non-conductive dielectric layer 20 is situated on the electrode 14, so as to cover the electrode. Depending on the design configuration of the semiconductor device, the dielectric layer 20 may also overlay portions of the substrate surface 12 that are not covered by the electrode 14. The dielectric layer is preferably formed by printing a suitable polymer, blend of polymers, or ceramic/metal oxide filled polymer, such as an aromatic polyurethane acrylate, a bisphenol A based polymer acrylate, or a novolak epoxy acrylate. These materials may be functionalized with chemical moieties to provide optimal adhesion to the subsequent layers that are printed. In the case of the ceramic/metal oxide filled polymer based dielectric, the particle size must be 5× smaller than the thickness of the dielectric layer. The purpose of the dielectric layer 20 is to insulate the gate electrode from other members. Other techniques of creating the dielectric layer may also be used, such as laminating, vacuum evaporation, a spin coating method or any method of depositing a layer of material with a nominal thickness of less than 10 micrometers and a capacitance of at least 0.4 nF/cm2. Additional electrodes 25, 26 are situated on top of the dielectric layer 20, and may be formed in a manner similar to that used to create the first electrode 14. In the case of an FET, electrode 25 acts as the source electrode, and electrode 26 acts as the drain electrode. In the printed electronics field the source, gate, and drain are printed using one or more of several possible methods common to the printing industry including but not limited to offset printing, gravure, flexo, ink jet, silk screening or pad printing. One skilled in the art will now appreciate that this arrangement provides a heterogeneous exposed surface consisting of the top and side surfaces of the electrodes 25, 26 and the exposed portions of the dielectric layer 20 that were not covered by the electrodes 25, 26. Chemically, the dielectric layer is a hydrocarbon polymer, and the electrodes are a printed conductive composite such as a metal with an oxide coating. Since these semiconductor devices are intended to be made in high volume using graphic arts technology, it is not feasible to maintain the device in a protective, non-oxidizing atmosphere, as in conventional wafer processing. Therefore a certain amount of oxide will always be present on the surface of the metal electrodes, the level of which is dependent on the reactivity of the metal employed in the electrodes.

Referring now to FIG. 3, all these exposed surfaces are simultaneously treated with a reactive silane to yield an interface 30 that presents a homogenous surface to which a semiconducting layer can strongly adhere. Also, the surface will nucleate growth of crystals of length greater than 0.5 microns and thickness of greater than 2× the electrode and dielectric surface roughness. Silanes are monomeric silicon molecules with four substituent groups attached to each silicon atom. These substituent groups can be nearly any combination of nonreactive, inorganically reactive, or organically reactive groups. Silicon will bond tenaciously to organic polymers when an organic group, such as aminopropyl, is attached to the silicon. This is because the reactivity of organic groups attached to silicon is similar to organic analogs in carbon chemistry. Organic reactivity occurs on the organic portion of the molecule and does not directly involve the silicon atom. Silicon will also bond tenaciously to inorganics such as metal and metal oxide. Inorganic reactivity represents the covalent bonds formed through oxygen to the silicon atom to form a siloxane type of bond. We have found that one reactive silane, hexamethyldisilazane (HMDS), is particularly useful in this regard. Other derivatives of HMDS, triethoxysilane, triethoxysilyl-methanol, aminopropyl triethoxysilane, or trimethoxysilyl propyl aniline can also be used. Hexamethyldisilazane is also known as 1,1,1,3,3,3-hexamethyldisilazane, has the empirical formula C₆H₁₉NSi₂, and the IUPAC name of [dimethyl-(trimethylsilylamino)silyl]methane. It is recognized as an adhesion promoter, and may be applied in vapor, liquid or solution form. HMDS can be applied by a variety of techniques, including vapor, direct application to a spinning substrate, spraying and dipping. While we have not completely investigated the exact mechanism that is responsible for the increase in adhesion, we believe that one factor is the reduction in surface tension. The reduction of surface tension occurs by means of a chemical reaction in which polar hydroxyl and oxide moieties on the surface of the metal electrode react with trimethylsilyl groups to produce a non-polar surface monolayer. The reaction will follow a two step sequence dependent on substrate condition. Water molecules adsorbed to the polar surface react first with HMDS to produce inert hexamethyldisiloxane and ammonia. The resulting dehydrated surface then reacts with more HMDS to produce a trimethylsilyl substituted hydroxyl or oxide species and unstable trimethylsilylamine. The trimethylsilylamine then reacts rapidly with another surface hydroxyl or alkoxide to produce ammonia and a trimethylsiloxy species. This reaction will continue, forming an interface layer 30, until the stearic constraints imposed by the large bulky trimethylsilyl groups will not permit further reaction. The interface layer generally contains chemically functional groups such as alkanes, aromatics, alcohols, amines, thiols, or derivatives. In the case of alkanes, the chemically functional group is CₙH₂ₙ₊₁ where n≦8. While not fully understood, we believe that thiols behave in a similar manner to the silanes, and can be used with efficacy as an interface layer. One thiol that we have found particularly useful is octanethiol. The treated interface layer 30 now provides a very wettable surface, with a contact angle generally less than 80 degrees with respect to an organic semiconductor ink, so that the organic semiconductor ink can effectively bind to the electrodes 25, 26 and the polymer of the dielectric layer 20.

Referring now to FIG. 4, a layer of an organic semiconductor, such as a pentacene ether, is formed on the interface layer 30 by printing. Materials that we find useful are bis(triisopropylsilylethynyl) or bis_triethylsilylethynyl pentacene. Some suitable printing methods are spraying, spinning, rod coating, roller coating, flexography, offset printing, inkjet printing, microdispensing, or gravure printing. Since the organic semiconductor is juxtaposed against a chemically homogenous surface (the treated interface layer 30), there are no discontinuities or difficult surfaces to deal with, and a strong bond between the organic semiconductor and the underlying material is formed. The arrangement of the FET device can also take on several different structures all of which share a common printed layer and have two electrically conducting elements, a source and drain, between which a semiconducting material is printed or deposited and which is in electrical contact with the semiconducting material. A non-conducting layer is deposited or printed between the semiconducting layer and a gate electrode. The order of deposition of these elements varies by application and deposition method and the examples in this document while calling out one or more specific transistor structures do not limit the usefulness of the embodiments to only these transistor structures but to organic film transistors in general.

In summary, a semiconductor device, such as an FET, uses a printable organic semiconductor on a polymer substrate using graphic arts printing technology. Two electrode layers are separated by a dielectric, and the exposed surfaces of the dielectric and the top electrode are treated with a reactive silane to alter the surface of the electrode and the dielectric sufficiently to allow an overlying organic semiconductor layer to have good adhesion to both the electrode and the dielectric. In the foregoing specification, specific embodiments have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The claimed invention is defined by the appended claims including any amendments made during the pendency of this application and all equivalents of those claims as issued.

What is claimed is:

1. A printed semiconductor device having a silane treated interface, comprising:
a substrate having a major surface;
a first electrode situated on a first portion of the major surface;
a dielectric layer disposed on the first electrode and on second portions of the major surface;
one or more second electrodes having a printed conductive composite layer, the second electrodes disposed on the dielectric layer so as to leave portions of the dielectric layer exposed, the conductive layer and the exposed dielectric layer portions comprising an heterogenic interface;
the heterogenic interface treated with a reactive silane sufficient to bind the printed conductive composite layer and the exposed dielectric layer portions with the reactive silane; and
an organic semiconductor layer, printed on the treated interface layer.

2. The printed semiconductive device as described in claim 1, wherein the substrate comprises a polymeric or poylmeric coated substrate selected from the group consisting of polyesters, polyimides, polyamides, polyamide-imides, polyetherimides, polyacrylates, polyethylene, polypropylene, epoxies, polyvinylidene chloride, polysiloxanes, polycarbonates, fabrics, and paper.

3. The printed semiconductive device as described in claim 1, wherein the first and second electrodes comprise one or more materials selected from the group consisting of aluminum, chromium, copper, gold, iron, nickel, palladium, platinum, silver, titanium, tin, tungsten, zinc, metal filled polymer composite, carbon filled polymer composite or blends thereof

4. The printed semiconductor device as described in claim 1, wherein the dielectric layer is printed.

5. The printed semiconductor device as described in claim 1, wherein the dielectric layer is a polymer having a capacitance of at least 0.4 nf/cm2.

6. The printed semiconductive device as described in claim 1, wherein the organic semiconductor layer is a pentacene ether.

7. The printed semiconductive device as described in claim 1, wherein printed on the heterogenic interface layer comprises spraying, spinning, rod coating, roller coating, flexography, offset printing, inkjet printing, microdispensing, or gravure printing.

8. The printed semiconductive device as described in claim 1, wherein the interface layer consists of alkanes, aromatics, alcohols, amines, thiols, or derivatives.

9. The printed semiconductive device as described in claim 8, wherein the chemically functional group comprises CₙH₂ₙ₊₁ where n≦8.

10. The printed semiconductive device as described in claim 8, wherein the interface layer provides a wettable surface having a contact angle <80 degrees with respect to semiconductor ink.

11. The printed semiconductive device as described in claim 1, wherein the reactive silane consists of hexamethyldisilazane, triethoxysilane, triethoxysilyl-methanol, aminopropyl triethoxysilane, trimethoxysilyl propyl aniline, or derivatives thereof

12. The printed semiconductive device as described in claim 1, wherein the printed semiconductive device is a field-effect transistor that shares a common printed layer.

13. A printed field-effect transistor having a silane treated interface, comprising:
a polymeric or polymeric coated substrate having a major surface and comprising one or more materials selected from the group consisting of polyesters, polyimides, polyamides, polyamide-imides, polyetherimides, polyacrylates, polyethylene, polypropylene, epoxies, polyvinylidene chloride, polysiloxanes, polycarbonates, fabrics, and paper;
a gate electrode printed on a first portion of the major surface;
a dielectric layer printed on the gate electrode and on second portions of the major surface;
source and drain electrodes each having a conductive composite layer, the source and drain electrodes disposed on the dielectric layer so as to leave portions of the dielectric layer exposed, the conductive composite layer and the exposed dielectric layer portions comprising an interface;
the interface treated with a reactive silane sufficient to bind the conductive layer and the exposed dielectric layer portions with the reactive silane; and
a pentacene ether semiconductor layer, printed on the interface layer, above the source and drain electrodes.

14. The printed field-effect transistor as described in claim 13, wherein the pentacene ether semiconductor layer comprises bis(triisopropylsilylethynyl) or bis_triethylsilylethynyl_pentacene.

15. The printed field-effect transistor as described in claim 13, wherein the first and second electrodes comprise one or more materials selected from the group consisting of aluminum, chromium, copper, gold, iron, nickel, palladium, platinum, silver, titanium, tin, tungsten, zinc, metal filled polymer composite, carbon filled polymer composite, conductive polymer or blends thereof.

16. The printed field-effect transistor as described in claim 13, wherein printed comprises spraying, spinning, rod coating, roller coating, flexography, offset printing, inkjet printing, microdispensing, or gravure printing.

17. The printed field-effect transistor as described in claim 13, wherein the reactive silane consists of hexamethyldisilazane or derivatives thereof

18. A printed semiconductor device having a silane bonding layer, comprising:
a polymeric or polymeric coated substrate having a major surface;
one or more first electrodes printed on the major surface;
a dielectric layer printed on the first electrodes and on portions of the major surface;
one or more second electrodes having a metal oxide layer, printed on the dielectric layer, revealing portions of the dielectric layer;
the metal oxide layer and the revealed portions of the dielectric layer treated with a reactive silane sufficient to form a silane bonding layer; and
a pentacene ether semiconductor layer, printed on the silane bonding layer.

19. The printed semiconductive device as described in claim 18, wherein the polymeric or polymeric coated substrate comprises one or more materials selected from the group consisting of polyesters, polyimides, polyamides, polyamide-imides, polyetherimides, polyacrylates, polyethylene, polypropylene, epoxies, polyvinylidene chloride, polysiloxanes, polycarbonates, fabrics, and paper.

20. The printed semiconductive device as described in claim 18, wherein the first and second electrodes comprise one or more materials selected from the group consisting of aluminum, chromium, copper, gold, iron, nickel, palladium, platinum, silver, titanium, tin, tungsten, zinc, metal filled polymer composite, carbon filled polymer composite, conductive polymer, or blends thereof.

21. The printed semiconductive device as described in claim 18, wherein the printed semiconductive device is a field-effect transistor that shares a common printed layer.

22. The printed semiconductive device as described in claim 18, wherein the reactive silane consists of hexamethyldisilazane or derivatives thereof

23. The printed semiconductive device as described in claim 18, wherein the pentacene ether semiconductor layer comprises (triisopropylsilylethynyl) or bis_triethylsilylethynyl pentacene.

24. A printed semiconductor device having a thiol treated interface, comprising:
a substrate having a major surface;
a first electrode situated on a first portion of the major surface;
a dielectric layer disposed on the first electrode and on second portions of the major surface;
one or more second electrodes having a printed conductive composite layer, the second electrodes disposed on the dielectric layer so as to leave portions of the dielectric layer exposed, the conductive layer and the exposed dielectric layer portions comprising an heterogenic interface;
the heterogenic interface treated with a reactive thiol sufficient to bind the printed conductive composite layer and the exposed dielectric layer portions with the reactive thiol; and
an organic semiconductor layer, printed on the treated interface layer.

25. The printed semiconductive device as described in claim 18, wherein the reactive thiol consists of octanethiol.
